(19) United States
(12) Patent Application Publication
(10) Pub. No.: US 2021/0288630 A1
(43) Pub. Date: Sep. 16, 2021

(54) FILTER

(71) Applicant: Samsung Electro-Mechanics Co., Ltd., Suwon-si (KR)

(72) Inventors: Yoon Sok PARK, Suwon-si (KR); Sung Tae KIM, Suwon-si (KR); Chan Hee PARK, Suwon-si (KR); Won Kyu JEUNG, Suwon-si (KR)

(73) Assignee: Samsung Electro-Mechanics Co., Ltd., Suwon-si (KR)

(21) Appl. No.: 16/908,929

(22) Filed: Jun. 23, 2020

(30) Foreign Application Priority Data
Mar. 13, 2020 (KR) 10-2020-0031589

(51) Int. Cl. H03H 9/54; H03H 9/205

(52) U.S. Cl. CPC H03H 9/542; H03H 9/205

(57) ABSTRACT

A filter includes a first chip having first frequency characteristics, a second chip having second frequency characteristics different from the first frequency characteristics, a first series portion and a second series portion connected in series between an input terminal and an output terminal, and each including at least one resonator, a first shunt portion disposed on the first chip and connected between a first node and a ground and a second shunt portion disposed on the second chip and connected between a second node and the ground, the first and second nodes being disposed between the input terminal and the output terminal, the first shunt portion and the second shunt portion each including at least one resonator, and a shunt trimming inductor connected to the first shunt portion in series.

### CROSS-REFERENCE TO RELATED APPLICATION(S)

This application claims the benefit under 35 USC 119(a) of Korean Patent Application No. 10-2020-0031589 filed on Mar. 13, 2020 in the Korean Intellectual Property Office, the entire disclosure of which is incorporated herein by reference for all purposes.

### BACKGROUND

### 1. Field

The following description relates to a filter.

### 2. Description of Background

With the rapid development of mobile communication devices, chemical and biological devices, demand for small and lightweight filters, oscillators, resonant elements and acoustic resonant mass sensors used in such devices has also been increasing.

A thin film bulk acoustic resonator (FBAR) is known as a means for implementing such a small and lightweight filter, an oscillator, a resonance element, and an acoustic resonance mass sensor. The thin-film bulk acoustic resonator has the advantage in that the resonator may be mass-produced at minimal costs and may be implemented in a microminiaturized size. In addition, a high quality factor (Q) value, a main characteristic of the filter, may be implemented, and the thin film bulk acoustic resonator may also be used in a frequency band of several GHz.

In general, a thin-film bulk acoustic resonator is formed of a structure including a resonator implemented by sequentially stacking a first electrode, a piezoelectric layer, and a second electrode on a substrate. Looking at the operational principle of the thin-film bulk acoustic resonator, first, an electric field is induced in the piezoelectric layer by electrical energy applied to first and second electrodes, and a piezoelectric phenomenon occurs in the piezoelectric layer by the induced electric field, so that the resonance part vibrates in a predetermined direction. As a result, a bulk acoustic wave is generated in the same direction as the vibration direction to cause resonance.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

Examples provide a filter capable of forming a pass band in a high frequency band.

In one general aspect, a filter includes a first chip having first frequency characteristics, a second chip having second frequency characteristics different from the first frequency characteristics, a first series portion and a second series portion connected in series between an input terminal and an output terminal, and each including at least one resonator, a first shunt portion disposed on the first chip and connected between a first node and a ground and a second shunt portion disposed on the second chip and connected between a second node and the ground, the first and second nodes being disposed between the input terminal and the output terminal, the first shunt portion and the second shunt portion each including at least one resonator, and a shunt trimming inductor connected to the first shunt portion in series.

Each of the first series portion, the second series portion, the first shunt portion, and the second shunt portion may include a first resonator and a second resonator connected to each other in series, and a third resonator and a fourth resonator connected to each other in series. Each of the first resonators and the second resonators may be connected in parallel to each of the respective third resonators and the fourth resonators.

The first series portion and the second series portion may be disposed on the second chip.

The shunt trimming inductor may be disposed on the first chip.

The filter may include a series trimming inductor connected to the first series portion in parallel.

The first series portion may be disposed on the first chip and the second series portion may be disposed on the second chip.

The first series portion and the first shunt portion may be disposed on the first chip.

The second series portion and the second shunt portion may be disposed on the second chip.

The series trimming inductor may be disposed on the first chip.

In another general aspect, a filter includes a first chip having first frequency characteristics, a second chip having second frequency characteristics different from the first frequency characteristics, a first series portion disposed on the first chip and a second series portion disposed on the second chip, the first series portion and the second series portion being connected in series between an input terminal and an output terminal, each of the first series portion and the second series portion including at least one resonator, a first shunt portion connected between a first node and a ground and a second shunt portion connected between a second node and the ground, the first and second nodes being disposed between the input terminal and the output terminal, the first shunt portion and the second shunt portion each including at least one resonator, and a series trimming inductor connected to the first series portion in parallel.

The first shunt portion and the second shunt portion may be disposed on the second chip.

The series trimming inductor may be disposed on the first chip.

The filter may include a shunt trimming inductor connected to the first shunt portion in series.

The first shunt portion may be disposed on the first chip and the second shunt portion may be disposed on the second chip.

The first shunt portion and the first series portion may be disposed on the first chip.

Other features and aspects will be apparent from the following detailed description, the drawings, and the claims.

### BRIEF DESCRIPTION OF THE DRAWINGS

FIG. 1 is a circuit diagram of a filter according to an example.

FIG. 2 illustrates a frequency response of the filter of FIG. 1.

FIG. 3 illustrates a resonator used in a plurality of series portions and a plurality of shunt portions according to an example.

FIGS. 4, 5, 6, 7 and 8 illustrate filters according to various examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative size, proportions, and depiction of elements in the drawings may be exaggerated for clarity, illustration, and convenience.

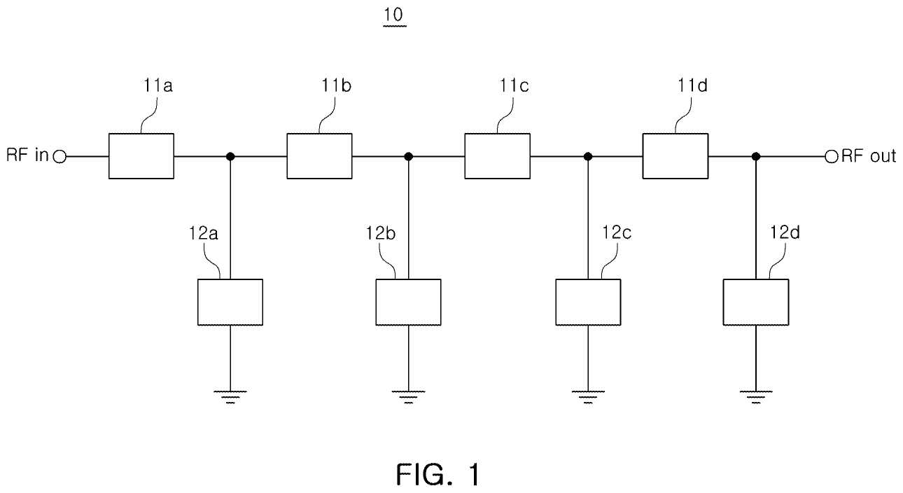

FIG. 1 is a circuit diagram of a filter according to an example.

Referring to FIG. 1, a filter 10 includes a plurality of series portions 11a, 11b, 11c and 11d, and a plurality of shunt portions 12a, 12b, 12c and 12d disposed between the plurality of series portions 11a, 11b, 11c and 11d and the ground.

The plurality of series portions 11a, 11b, 11c and 11d may be disposed in series between an input terminal RFin to which an input signal is input and an output terminal RFout to which an output signal is output. The plurality of shunt portions 12a, 12b, 12c and 12d may be disposed between different nodes between the input terminal RFin and the output terminal RFout, and the ground.

The filter 10 may be formed of a ladder type structure, as illustrated in FIG. 1, or in the manner different therefrom, may be formed of a lattice type structure.

Each of the plurality of series portions 11a, 11b, 11c and 11d and the plurality of shunt portions 12a, 12b, 12c and 12d may include at least one resonator.

At least one resonator provided in each of the plurality of series portions 11a, 11b, 11c and 11d may be referred to as a series resonator SE, and at least one resonator provided in each of the plurality of shunt portions 12a, 12b, 12c and 12d may be referred to as a shunt resonator SH.

In FIG. 1, the filter 10 is illustrated as having four series portions 11a, 11b, 11c and 11d and four shunt portions 12a, 12b, 12c and 12d, but the number of the series portions 11a, 11b, 11c and 11d and the shunt portions 12a, 12b, 12c and 12d may be changed.

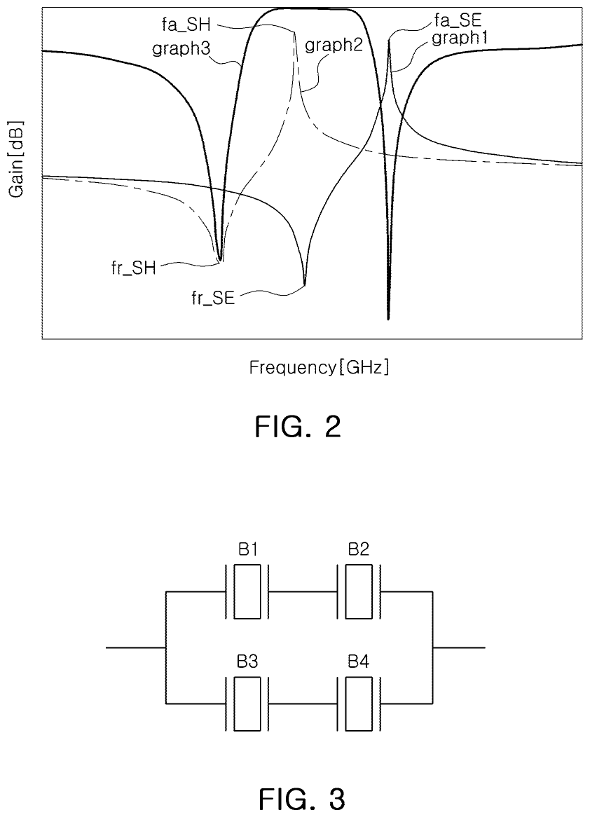

FIG. 2 illustrates the frequency response of the filter of FIG. 1.

Referring to FIG. 2, the first graph (graph1) illustrates a frequency response (Z, Impedance) by the series resonator (SE) provided in the plurality of series portion 11a, 11b, 11c and 11d, the second graph (graph2) represents a frequency response (Z, Impedance) by the shunt resonator (SH) provided in the plurality of shunt portions 12a, 12b, 12c and 12d, and the third graph (graph3) represents a frequency response (S-parameter) by the filter 10 including the series resonator (SE) and the shunt resonator SH.

The frequency response by the series resonator SE has a resonant frequency fr_SE and an antiresonance frequency fa_SE, and the frequency response by the shunt resonator SH has a resonant frequency fr_SH and an antiresonance frequency fa_SH.

Referring to the frequency response of the filter 10, the overall bandwidth of the filter 10 may be determined by the resonant frequency fr_SH of the shunt resonator SH and the antiresonance frequency fa_SE of the series resonator SE.

In order for the filter to be implemented as a bandpass filter, the resonant frequency fr_SE of the series resonator (SE) is designed to be higher than the resonant frequency fr_SH of the shunt resonator (SH), and the antiresonance frequency fa_SE of the series resonator (SE) is designed to be higher than the antiresonance frequency fa_SH of the resonator (SH).

As various frequency bands have been used in wireless communications, in addition to the low frequency bands such as 2 GHZ to 2.5 GHZ, it is expected that high frequency bands such as 3.5 GHZ to 6 GHZ will be used, and in addition, it is expected that the wide pass bandwidth of 500 MHz or more will be used, compared to the existing 100 to 200 MHz pass bandwidth.

To form a pass band in a relatively high frequency band, it is necessary to reduce the thickness of the resonator. However, in case of reducing the thickness of the resonator, there is a problem in terms of being vulnerable to the supplied power.

FIG. 3 illustrates a resonator used in a plurality of series portions and a plurality of shunt portions according to an example.

Referring to FIGS. 1 and 3, each of the plurality of series portions 11a, 11b, 11c and 11d and the plurality of shunt portions 12a, 12b, 12c and 12d may include a first resonator B1 and a second resonator B2 connected to each other in series, and a third resonator B3 and a fourth resonator B4 connected to each other in series. The first resonator B1 and the second resonator B2 connected to each other in series, and the third resonator B3 and the fourth resonator B4 connected to each other in series, may be connected to each other in parallel.

According to an example, as the plurality of series portions 11a, 11b, 11c and 11d and the plurality of shunt portions 12a, 12b, 12c and 12d, each include the first resonator B1, the second resonator B2, the third resonator B3 and the fourth resonator B4 illustrated in FIG. 3, a pass band may be formed in a high frequency band, while being robust to the supplied power.

However, in the case in which the plurality of series portions 11a, 11b, 11c and 11d and the plurality of shunt portions 12a, 12b, 12c and 12d each include a plurality of resonators, the process spread may increase as the area increases.

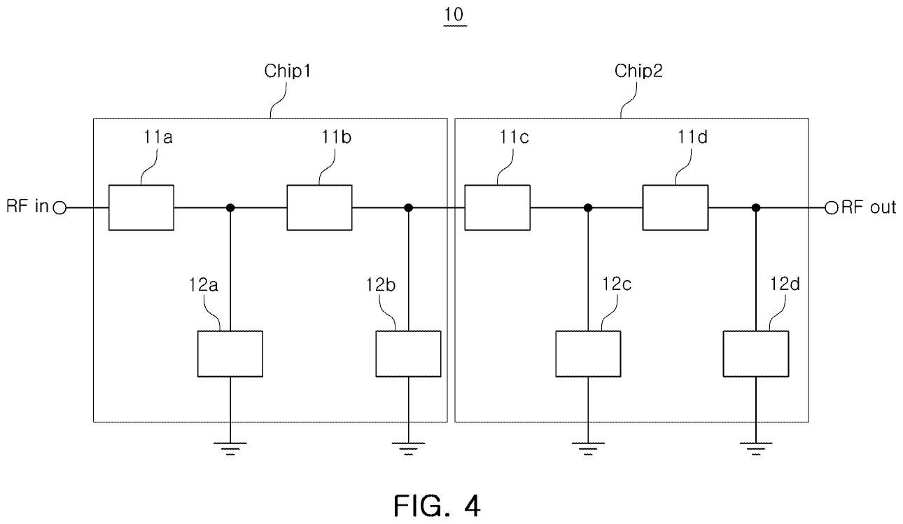

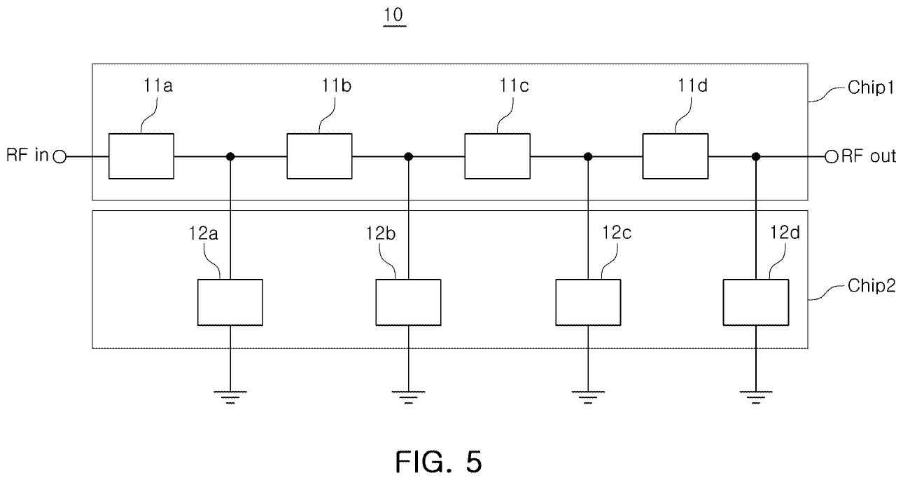

FIGS. 4 and 5 illustrate filters according to various examples.

Referring to FIGS. 4 and 5, the filter 10 according to an example may be manufactured by being divided into a plurality of chips. For example, the filter 10 may be manufactured by being divided into a first chip (Chip1) and a second chip (Chip2). In FIGS. 4 and 5, the filter 10 is illustrated to be manufactured by being divided into two chips, but the number of chips may be changed.

The first chip (Chip1) may include a portion of the plurality of series portions 11a, 11b, 11c and 11d and the plurality of shunt portions 12a, 12b, 12c and 12d, and the second chip (Chip2) may include the rest of the plurality of series portions 11a, 11b, 11c and 11d and the plurality of shunt portions 12a, 12b, 12c and 12d.

For example, referring to FIG. 4, the first chip (Chip1) may include a first series portion 11a, a second series portion 11b, a first shunt portion 12a, and a second shunt portion 12b. The second chip (Chip2) may include a third series portion 11c, a fourth series portion 11d, a third shunt portion 12c, and a fourth shunt portion 12d.

As another example, referring to FIG. 5, the first chip (Chip1) includes a first series portion 11a, a second series portion 11b, a third series portion 11c, and a fourth series portion 11d. The second chip (Chip2) may include a first shunt portion 12a, a second shunt portion 12b, a third shunt portion 12c, and a fourth shunt portion 12d.

According to an example, by manufacturing the filter 10 such that the plurality of series portions (11a, 11b, 11c and 11d) and the plurality of shunt portions (12a, 12b, 12c and 12d) may be divided and disposed in different chips, even when the area of the filter is increased, the process spread may be prevented from being increased.

On the other hand, to precisely match the pass band, frequency characteristics of some series resonators of the plurality of series resonators of the filter and frequency characteristics of the remaining series resonators may be designed differently, and frequency characteristics of some shunt resonators of the plurality of shunt resonators of the filter and frequency characteristics of the remaining shunt resonators may be designed differently. By varying the thicknesses of the series resonator and the shunt resonator, the frequency characteristics of the series resonator and the shunt resonator may be adjusted.

However, compared with the case in which only the frequency characteristics of the series resonator and the shunt resonator are designed differently, when the frequency characteristics of some series resonators and the other series resonators are designed differently and the frequency characteristics of some shunt resonators and the other shunt resonators are designed differently, since the thicknesses of a plurality of resonators should be manufactured differently, there is a problem in which the process yield may be deteriorated.

According to an example of the present disclosure, the filter is manufactured to include a plurality of chips, and the frequency characteristics of a plurality of resonators provided in one of the plurality of chips are limited to two, thereby improving the process yield.

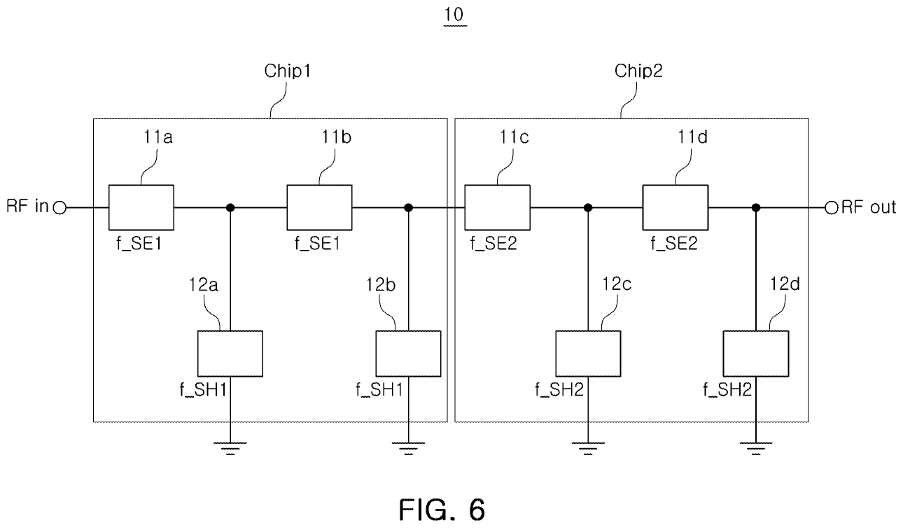

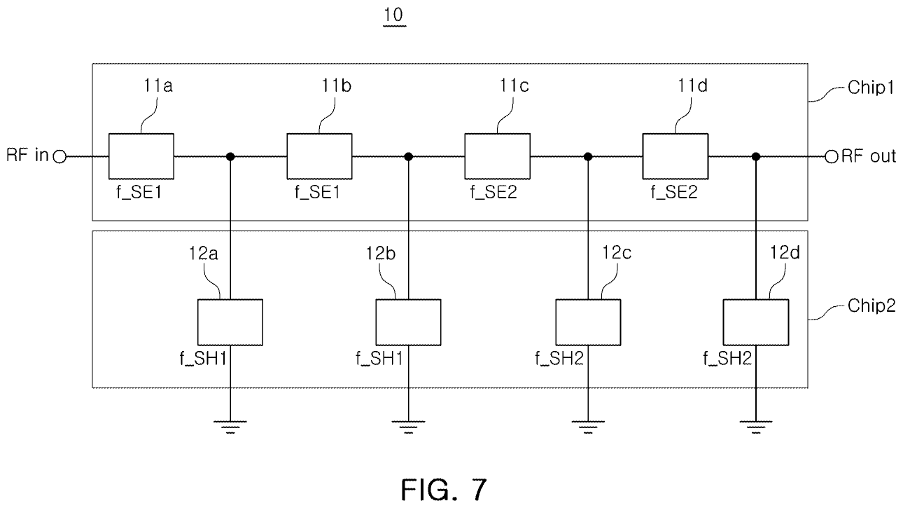

FIGS. 6 and 7 illustrate filters according to various examples.

Referring to FIG. 6, a first series portion 11a and a second series portion 11b included in a first chip 1 (Chip1), and a third series portion 11c and a fourth series portion 11d included in a second chip 2 (Chip2), may have different frequency characteristics. For example, the first series portion 11a and the second series portion 11b may have a first series frequency characteristic (f_SE1), and the third series portion 11c and the fourth series portion 11d may have a second series frequency characteristic (f_SE2).

A first shunt portion 12a and a second shunt portion 12b included in the first chip (Chip1) may have frequency characteristics different from frequency characteristics of a third shunt portion 12c and a fourth shunt portion 12d included in the second chip (Chip2). For example, the first shunt portion 12a and the second shunt portion 12b may have a first shunt frequency characteristic (f_SH1), and the third shunt portion 12c and the fourth shunt portion 12d may have a second shunt frequency characteristic (f_SH2).

Referring to FIG. 7, the first series portion 11a and the second series portion 11b included in the first chip (Chip1) may have different frequency characteristics from the third series portion 11c and the fourth series portion 11d. For example, the first series portion 11a and the second series portion 11b may have a first series frequency characteristic (f_SE1), and the third series portion 11c and the fourth series portion 11d may have a second series frequency characteristic (f_SE2).

The first shunt portion 12a and the second shunt portion 12b included in the second chip (Chip2) may have different frequency characteristics from the third shunt portion 12c and the fourth shunt portion 12d. For example, the first shunt portion 12a and the second shunt portion 12b may have a first shunt frequency characteristic (f_SH1), and the third shunt portion 12c and the fourth shunt portion 12d may have a second shunt frequency characteristic (f_SH2).

According to an example, frequency characteristics of some series resonators and the remaining series resonators are designed differently, and frequency characteristics of some shunt resonators and the remaining shunt resonators are designed differently, thereby precisely matching the pass bands, and in addition, improving the process yield by limiting the frequency characteristics of the plurality of resonators provided in one chip to two.

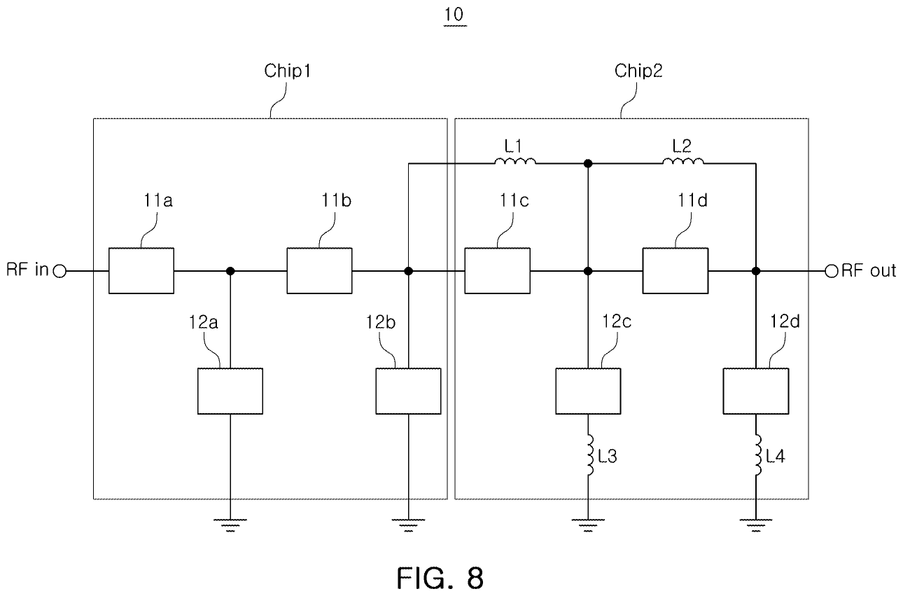

FIG. 8 illustrates a filter according to an example.

Referring to FIG. 8, the filter 10 may further include at least one trimming inductor.

Referring to FIG. 8, the filter 10 may further include a first trimming inductor L1 connected to the third series portion 11c in parallel, a second trimming inductor L2 connected to the fourth series portion 11d in parallel, a third trimming inductor L3 disposed between the third shunt portion 12c and the ground and connected in series with the third shunt portion 12c, and a fourth trimming inductor L4 disposed between the fourth shunt portion 12d and the ground and connected to the fourth shunt portion 12d in series. The first trimming inductor L1 and the second trimming inductor L2 may be referred to as a series trimming inductor, and the third trimming inductor L3 and the fourth trimming inductor L4 may be referred to as a shunt trimming inductor.

Referring to FIG. 8, the first chip (Chip1) may include the first series portion 11a, the second series portion 11b, the first shunt portion 12a, and the second shunt portion 12b. The second chip (Chip2) may include the third series portion 11c, the fourth series portion 11d, the third shunt portion 12c, the fourth shunt portion 12d, the first trimming inductor L1, the second trimming inductor L2, the third trimming inductor L3, and the fourth trimming inductor L4.

In FIG. 8, the first series portion 11a and the second series portion 11b may have the same series frequency characteristics as those of the third series portion 11c and the fourth series portion 11d, and the first shunt portion 12a and the second shunt portion 12b may have the same shunt frequency characteristic as that of the third shunt portion 12c and the fourth shunt portion 12d. In this case, by the first trimming inductor L1 and the second trimming inductor L2, the series frequency characteristics of the first chip (Chip1) and the second chip (Chip2) may be different, and by the third trimming inductor L3 and the fourth trimming inductor L4, the shunt frequency characteristics of the first chip (Chip1) and the second chip (Chip2) may be different.

The filter 10 according to the example of FIG. 8 may precisely match the pass band, through the first trimming inductor L1 connected to the third series portion 11c in parallel, the second trimming inductor L2 connected to the fourth series portion 11d in parallel, the third trimming inductor L3 disposed between the third shunt portion 12c and the ground, and the fourth trimming inductor L4 disposed between the fourth shunt portion 12d and the ground.

However, in the case in which the first trimming inductor L1, the second trimming inductor L2, the third trimming inductor L3, and the fourth trimming inductor L4 are formed by a circuit pattern, the overall process yield may be lowered.

Therefore, in the case of the filter 10 according to an example of the present disclosure, the first series portion 11a, the second series 11b, the first shunt 12a and the second shunt 12b may be manufactured as the first chip (Chip1), and the third series portion 11c, the fourth series portion 11d, the third shunt portion 12c, the fourth shunt portion 12d, the first trimming inductor L1, the second trimming portion L2, the third trimming inductor L3 and the fourth trimming inductor L4 may be manufactured as the second chip (Chip2), thereby improving a process yield.

On the other hand, although FIG. 8 illustrates that the third series portion 11c and the fourth series portion 11d are connected to the trimming inductor in parallel, and the third shunt portion 12c and the fourth shunt portion 12d are connected to the trimming inductor in series; according to an example, the trimming inductor may only be connected to the third series portion 11c and the fourth series portion 11d in parallel, or the trimming inductor may only be connected to the third shunt portion 12c and the fourth shunt portion 12d in series.

When the first trimming inductor L1 and the second trimming inductor L2 are connected in parallel only to the third series portion 11c and the fourth series portion 11d, only the first trimming inductor L1, the second trimming inductor L2, the third series portion 11c and the fourth series portion 11d may be manufactured as at least one of chips separated from a single chip; and the first series portion 11a, the second series portion 11b, the first shunt portion 12a, the second shunt portion 12b, the third shunt portion 12c and the fourth shunt portion 12d may be manufactured as the single chip.

When the third trimming inductor L3 and the fourth trimming inductor L4 are connected in series only to the third shunt portion 12c and the fourth shunt portion 12d, only the third trimming inductor L3, the fourth trimming inductor L4, the third shunt portion 12c and the fourth shunt portion 12d may be formed as at least one of chips separated from a single chip; and the first series portion 11a, the second series portion 11b, and the third series portion 11c, the fourth series portion 11d, the first shunt portion 12a and the second shunt portion 12b may be formed as the single chip.

As set forth above, the filter according to an example is formed of at least two chips, thereby improving a process yield while preventing process spread from being increased.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A filter comprising:
a first chip having first frequency characteristics;
a second chip having second frequency characteristics different from the first frequency characteristics;
a first series portion and a second series portion connected in series between an input terminal and an output terminal, each of the first series portion and the second series portion including at least one resonator;
a first shunt portion disposed on the first chip and connected between a first node and a ground and a second shunt portion disposed on the second chip and connected between a second node and the ground, the first and second nodes being disposed between the input terminal and the output terminal, the first shunt portion and the second shunt portion each including at least one resonator; and
a shunt trimming inductor connected to the first shunt portion in series.

2. The filter of claim 1, wherein each of the first series portion, the second series portion, the first shunt portion, and the second shunt portion comprises a first resonator and a second resonator connected to each other in series, and a third resonator and a fourth resonator connected to each other in series,
wherein each of the first resonators and the second resonators are connected in parallel to each of the respective third resonators and the fourth resonators.

3. The filter of claim 1, wherein the first series portion and the second series portion are disposed on the second chip.

4. The filter of claim 1, wherein the shunt trimming inductor is disposed on the first chip.

5. The filter of claim 1, further comprising a series trimming inductor connected to the first series portion in parallel.

6. The filter of claim 5, wherein the first series portion is disposed on the first chip and the second series portion is disposed on the second chip.

7. The filter of claim 5, wherein the first series portion and the first shunt portion are disposed on the first chip.

8. The filter of claim 7, wherein the second series portion and the second shunt portion are disposed on the second chip.

9. The filter of claim 5, wherein the series trimming inductor is disposed on the first chip.

10. A filter comprising:
a first chip having first frequency characteristics;
a second chip having second frequency characteristics different from the first frequency characteristics;
a first series portion disposed on the first chip and a second series portion disposed on the second chip, the first series portion and the second series portion being connected in series between an input terminal and an output terminal, each of the first series portion and the second series portion comprising at least one resonator;
a first shunt portion connected between a first node and a ground and a second shunt portion connected between a second node and the ground, the first and second nodes being disposed between the input terminal and the output terminal, the first shunt portion and the second shunt portion each comprising at least one resonator; and
a series trimming inductor connected to the first series portion in parallel.

11. The filter of claim 10, wherein each of the first series portion, the second series portion, the first shunt portion, and the second shunt portion comprises a first resonator and a second resonator connected to each other in series, and a third resonator and a fourth resonator connected to each other in series,
wherein each of the first resonators and the second resonators are connected in parallel with each of the respective third resonators and the fourth resonators.

12. The filter of claim 10, wherein the first shunt portion and the second shunt portion are disposed on the second chip.

13. The filter of claim 10, wherein the series trimming inductor is disposed on the first chip.

14. The filter of claim 10, further comprising a shunt trimming inductor connected to the first shunt portion in series.

15. The filter of claim 14, wherein the first shunt portion is disposed on the first chip and the second shunt portion is disposed on the second chip.

16. The filter of claim 14, wherein the first shunt portion and the first series portion are disposed on the first chip.
